(19) United States
(12) Patent Application Publication
(10) Pub. No.: US 2010/0327278 A1
(43) Pub. Date: Dec. 30, 2010

(54) LAMINATED STRUCTURES

(75) Inventor: Doyeol AHN, Seoul (KR)

Correspondence Address: Workman Nydegger;1000 Eagle Gate Tower, 60 East South Temple, Salt Lake City, UT, 84111, US

(73) Assignee: UNIVERSITY OF SEOUL INDUSTRY COOPERATION FOUNDATION, Seoul (KR)

(21) Appl. No.: 12/494,056

(22) Filed: Jun. 29, 2009

(51) Int. Cl. H01L 29/10; H01L 29/15; H01L 21/16

(52) U.S. Cl. 257/43; 257/76; 438/104; 257/E29.002; 257/E29.003; 257/E21.459

(57) ABSTRACT

Laminated structures having improved optical gain are provided. In one embodiment, a laminated structure includes a first cladding layer having at least two barrier layers which have different energy band gaps, an active layer formed on the first cladding layer and having an active layer energy band gap, and a second cladding layer formed on the active layer and including at least two barrier layers which have different energy band gaps. The first cladding layer and the second cladding layer may be doped with a different type of dopant.

### BACKGROUND

Wide band-gap (WBG) semiconductors based on hetero-structures have recently attracted a great deal of attention due to characteristics that result from a large band gap. In particular, wide band-gap (WBG) semiconductors can be used in a variety of optoelectronic devices operating in short wavelength regions, such as photovoltaic cells, light emitting diodes, and laser diodes. The efficiency of optoelectronic devices is related to the quantum efficiency which is a measurement of electrical sensitivity to light. The quantum efficiency is determined by optical gain.

### SUMMARY

In one embodiment, a laminated structure includes a first cladding layer including at least two barrier layers which have different energy band gaps. The first cladding layer may be doped with a first dopant. An active layer is located on the first cladding layer and includes an active layer energy band gap which has a smaller energy band gap than at least one of the energy band gaps of the at least two barrier layers of the first cladding layer. A second cladding layer is located on the active layer and includes at least two barrier layers which have different energy band gaps. The second cladding layer may be doped with a second dopant different than the first dopant, and at least one of the two barrier layers of the second cladding layer has a larger energy band gap than the active layer band gap.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram showing an illustrative embodiment of a laminated structure.

FIG. 2 is a sectional view of an illustrative embodiment of a light emitting layer of the laminated structure shown in FIG. 1

FIG. 3 is a graph illustrating optical gain for the light emitting layer shown in FIG. 2.

FIG. 4 is an energy band diagram for the light emitting layer shown in FIG. 2.

FIG. 5 is a sectional view of another illustrative embodiment of the light emitting layer of the laminated structure shown in FIG. 1.

FIG. 6 is an energy band diagram for the light emitting layer shown in FIG. 5.

FIG. 7 is a sectional view of still another illustrative embodiment of the light emitting layer of the laminated structure shown in FIG. 1.

FIG. 8 is an energy band diagram for the light emitting layer shown in FIG. 7.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

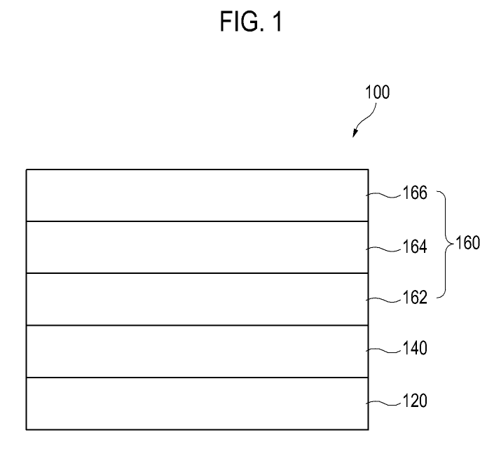

FIG. 1 shows an illustrative embodiment of a laminated structure 100. As shown in FIG. 1, laminated structure 100 may include a substrate 120, a buffer layer 140, and a light emitting layer 160. In some embodiments, substrate 120, buffer layer 140, and light emitting layer 160 are stacked in sequence. Substrate 120 may be formed from nitride semiconductor materials, such as gallium nitride (GaN), or other materials, such as sapphire (Al₂O₃), silicon carbide (SiC), silicon (Si), or gallium arsenide (GaAs). Buffer layer 140 may be formed to reduce the difference in lattice constants and thermal expansion coefficients between substrate 120 and light emitting layer 160. For example, if substrate 120 is made from Al₂O₃, buffer layer 140 may be formed from AlN, AlGaN, or SiC to grow a nitride semiconductor layer, such as InGaN, thereon. Alternatively, buffer layer 140 may be optional and may not be provided. For example, if substrate 120 is made from a nitride semiconductor, substrate 120 may contact light emitting layer 160 without any buffer layer interposed therebetween.

Light emitting layer 160 may include a first cladding layer 162, an active layer 164, and a second cladding layer 166. In some embodiments, first cladding layer 162, active layer 164, and second cladding layer 166 are stacked over buffer layer 140 or substrate 120 in sequence. First cladding layer 162, active layer 164, and second cladding layer 166 may be made of any material to form a quantum well in which electron-hole recombination occurs. In some embodiments, the quantum well may include quantum dots or quantum wires.

In some embodiments, first cladding layer 162, active layer 164, and second cladding layer 166 may include a nitride based semiconductor. For example, a nitride based semiconductor may include indium (I), gallium (Ga), or nitrogen (N). In other embodiments, first cladding layer 162, active layer 164, and second cladding layer 166 may include Group II-VI compounds, such as ZnO, CdZnO, MgZnO, ZnS, CdZnS, or ZnSSe. For example, active layer 164 may include ZnO, and first and second cladding layers 162 and 166 may include CdZnO, or MgZnO.

First and second cladding layers 162 and 166 may be either an n-type or a p-type cladding layer. First and second cladding layers 162 and 166 may be doped with different types of dopants. For example, if first cladding layer 162 is doped with at least one n-type dopant selected from Si, Ge, or Sn, second cladding layer 166 is doped with at least one p-type dopant selected from Zn, Mg, Ca, or Be, and vice versa. In some embodiments, first and second cladding layers 162 and 166 may be divided into at least two sub-layers.

Laminated structure 100 may further include electrode pads (not shown) which allow a voltage to be applied to operate a device, such as an optoelectronic device, employing laminated structure 100. In some embodiments, one electrode pad may be provided on second cladding layer 166, and another electrode pad may be provided under buffer layer 140 or first cladding layer 162. In other embodiments, one electrode pad may be stacked on second cladding layer 166, and another electrode pad may be stacked on first cladding layer 162 which is covered partially by active layer 164. One of the electrode pads may have a laminated structure of Ni/Au or Ag/Au while another electrode pad may have a laminated structure of Ti/Al.

Each layer of laminated structure 100 may be formed using any of a variety of well-known disposition techniques such as e-beam evaporation, physical vapor deposition (PVD), chemical vapor deposition (CVD), plasma laser deposition (PLD), dual-type thermal evaporation, sputtering, and the like.

As described, different layers of laminated structure 100 may have different materials to form the quantum well therein, and the different materials may have different lattice constants. Therefore, laminated structure 100 may have strains which result from a lattice mismatch between the layers. In the strained layers, there is a piezoelectric effect which may be increased as the strains in the layers are increased. The layers may further include a spontaneous polarization that materials naturally possess in the absence of an external electric field. The piezoelectric polarization and the spontaneous polarization in the layers may generate an electric filed (hereinafter, “internal electric field”). By way of example, when laminated structure 100 is employed in an optoelectronic device, the internal electric field generated in light emitting layer 160 may reduce the optical gain. Specifically, the internal electric filed is related to the line-shape function Cₗₘ^{ησ}( k̅ [symbol] ) and the optical dipole matrix Mₗₘ^{ησ}( k̅ [symbol] ), which determine the optical gain g(ω) as given by

$$\begin{matrix}g ( ω ) = \frac{ω μ c}{n \text{?} V} \sum \text{?} {\sum }_{\overline{k}} \text{?} {\vert \hat{ɛ} \cdot {M}^{η σ} \text{?} ( \overline{k} \text{?} ) \vert}^{2} ( {f}_{c}^{l} - {f}_{h σ}^{m} ) {C}^{η σ} \text{?} ( \overline{k} \text{?} ) & [ 1 ] \\ \text{?} \text{indicates text missing or illegible when filed} & \end{matrix}$$

where ω is the angular frequency, μ is the permeability, ηᵣ is the refractive index, c is the speed of light in free space, V is the volume, f_{c}^{l} and f_{hσ}^{m} are the Fermi functions for the Ith subband in the conduction band and the mth subband in the valence band of H^{σ}, respectively, and [symbol] is the unit vector in the direction of the photon polarization.

The line-shape function Cₗₘ^{ησ}(k [symbol] ) can be written as

$$\begin{matrix}{C}^{η σ} \text{?} ( \overline{k} \text{?} ) = \frac{\{ \begin{matrix}Re {Ξ}^{η σ} \text{?} ( 0 , {Δ}^{η σ} \text{?} ( \vec{k} \text{?} ) ) ( 1 - Re {q}^{η σ} ( \overline{k} \text{?} ) ) - \\ Im {Ξ}^{η σ} \text{?} ( 0 , {Δ}^{η σ} \text{?} ( \vec{k} \text{?} ) ) Im {q}^{η σ} \text{?} ( \overline{k} \text{?} )\end{matrix} \}}{{( 1 - Re {q}^{η σ} \text{?} ( \overline{k} \text{?} ) )}^{2} + {( Im {q}^{η σ} \text{?} ( \overline{k} \text{?} ) )}^{2}} & [ 2 ] \\ \text{?} \text{indicates text missing or illegible when filed} & \end{matrix}$$

where Reqₗₘ^{ησ}( k̅ [symbol] ) and Im qₗₘ^{ησ}( k̅ [symbol] ) are the real and the imaginary part of the Coulomb interaction between the electron in the Ith conduction sub-band with a spin state η, and the hole in the mth valence sub-band of the 3×3 block Hamiltonian H^{σ} in the presence of photon fields, respectively. Re Ξₗₘ^{ησ}(0,Δₗₘ^{ησ}( k̅ [symbol] )) and ImΞₗₘ^{ησ}(0,Δₗₘ^{ησ}( k̅ [symbol] )) are the real and the imaginary part of the non-Markovian lineshape, which can be written as follows, where Δₗₘ^{ησ}(k [symbol] ) is defined by Equation [5].

$$\begin{matrix}Re {Ξ}^{ησ} \text{?} ( 0 , {Δ}^{ησ} \text{?} ( \vec{k} \text{?} ) ) = \sqrt{\frac{π {τ}_{i n} ( \vec{k} \text{?} , ℏ ω ) τ \text{?}}{2 {ℏ}^{2}}} exp ( - \frac{{τ}_{i n} ( \vec{k} \text{?} , ℏ ω ) τ \text{?}}{2 {ℏ}^{2}} {Δ}^{ησ} \text{?} {( \vec{k} \text{?} )}^{2} ) & [ 3 ] \\ Im {Ξ}^{ησ} \text{?} ( 0 , {Δ}^{ησ} \text{?} ( \vec{k} \text{?} ) ) = \frac{τ \text{?}}{ℏ} {\int }_{0}^{∞} exp ( - \frac{τ \text{?}}{2 {τ}_{i n} ( \vec{k} \text{?} , ℏ ω )} {t}^{2} ) sin ( \frac{{Δ}^{ησ} \text{?} ( \vec{k} \text{?} ) {τ}_{c}}{ℏ} t ) & [ 4 ] \\ {Δ}^{ησ} \text{?} ( \vec{k} \text{?} ) = {E}_{l}^{c} ( \vec{k} \text{?} ) - {E}_{m}^{h σ} ( \vec{k} \text{?} ) + {E}_{G} + Δ {E}_{SX} + Δ {E}_{CH} - ℏ ω & [ 5 ] \\ \text{?} \text{indicates text missing or illegible when filed} & \end{matrix}$$

where Eₗ^{c}( k̅ [symbol] ) and Eₘ^{ησ}( k̅ [symbol] ) are the Ith sub-band energy in the conduction band and the mth sub-band energy in the valence band of H^{σ} at k̅ [symbol] , respectively, E_{G} is the band gap energy, ΔE_{SX} is the screened exchange energy change, ΔE_{CH} is the Coulomb-hole contribution to the band gap renormalization, τᵢₙ is the intraband relaxation time; τ_{c} is the coherence time, [symbol] and is the Plank constant.

The intraband relaxation time τᵢₙ, which is one of the parameters that determine the line-shape function Cₗₘ^{ησ}( k̅ [symbol] ), is related to an intraband relaxation. In general, intraband relaxation refers to the position transition of the electrons within an energy band, and the intraband relaxation time τᵢₙ refers to a time required for an electron to travel a lattice distance. As the internal electric field increases, the electrons are more likely to scatter with the phonons and to move to other positions within the energy band. As a result, the electrons may move from their original position in which the electrons effectively recombine with the holes, so that the optical gain may be reduced.

The optical dipole matrix Mₗₘ^{ησ}( k̅ [symbol] ), which refers to the dipole matrix element between the Ith conduction subband with a spin state η and the mth valence subband of the 3×3 block Hamiltonian H^{σ}, is related to the electron-hole separation. That is, the dipole matrix element is decreased as the electrons and the holes traveling within the conduction band and the valence band, respectively, are further apart from each other. Then, the internal electric field may force the electrons and the holes to move in opposite directions so that the dipole matrix element may decrease. Therefore, the optical gain may be reduced when the internal electric field in light emitting layer 160 is increased.

As discussed, the dipole matrix element and the line-shape function, in which the optical gain is proportional, are affected by the internal electric field in light emitting layer 160. The optical gain, therefore, is improved when the internal electric field in light emitting layer 160 is reduced.

The internal electric field generated from piezoelectric polarization can be reduced by adjusting the strains in the layers. The strains produced in the i-th layer of laminated structure 100 depend on a position in the i-th layer and the lattice mismatch with the other layers of laminated structure 100. The strain at each position in each layer can be calculated when dimensions and/or the composition of each layer are given. For example, the strain εₖₘᵢ at a certain position in the i-th layer can be computed by using Equations [6]-[7] below.

$$\begin{matrix} {λ}_{ikim} \frac{\partial {G}_{i n} ( \vec{r} )}{\partial {x}_{k} \partial {x}_{m}} = - δ ( \vec{r} ) {δ}_{i n} & [ 6 ] \\ {ɛ}_{ij} ( \vec{r} ) = {ɛ}_{ij}^{T} χ ( \vec{r} ) + \frac{1}{2} \int [ \frac{\partial {G}_{i n} ( \vec{r} - r \text{?} )}{\partial {x}_{j} \partial {x}_{k}} + \frac{\partial {G}_{jn} ( \vec{r} - r \text{?} )}{\partial {x}_{i} \partial {x}_{k}} ] λ \text{?} {ɛ}_{pr}^{T} d V & [ 7 ] \\ \text{?} \text{indicates text missing or illegible when filed} & \end{matrix}$$

The solution of Equation [6] is Green's Function for anisotropic elastic media, which is used to calculate the strain. λᵢₖₗₘ in Equation 6 is the tensor of elastic moduli. Equation [6] is related to the strain tensor εᵢⱼ( r̅) at a position within the i-th layer. In Equation [7], εᵢⱼ^{r} is the initial strain tensor caused by the lattice mismatch between the i-th layer and the j-th layer, and X represents the characteristic function which gives unity within the region of certain pre-specified volume and vanishes otherwise. Further, Equation [7] includes a volume integral with respect to the volume V the i-th layer so that Equation [6] requires conditions relating to areas and thicknesses of the layers to determine strains at specified positions. Therefore, upon assuming an area, a thickness, and a composition of each layer of laminated structure 100 to specific values or a specific composition, the strains εₖₘᵢ at the positions within a layer can be calculated from Equations [6]-[7]. By averaging the strains εₖₘᵢ at the positions within the layer, the averaged strain [symbol] εₖₘ [symbol] in the layer may be obtained. In some embodiments, the averaged strain [symbol] εₖₘ [symbol] may be used as an effective strain in the layer. Further, upon assuming various laminated structures 100 which have different areas and thicknesses and compositions of the layers, various strains in laminated structures 100 may be obtained.

The above calculated strains can be used to calculate the internal electric field in each layer. The total polarization Pₜ is provided as a sum of the spontaneous polarization Pₛₚ and the piezoelectric polarization P_{z}, which is induced by the strain in the layer, as shown in Equation [8] below:

Pₜ=Pₛₚ+P_{z} [8]

where the spontaneous polarization Pₛₚ may be obtained by using experimental values, as described in Bernardini and Fiorentini, “Nonlinear Macroscopic Polarization in III-VNitride Alloys,” Physical Review B, 64:085207 (2001) incorporated by reference herein in its entirety. The piezoelectric polarization in the i-th layer P_{zi} may be calculated using Equation [9] below:

$${P}_{zi} = 2 {d}_{31} ( {c}_{11} + {c}_{12} - \frac{2 {c}_{13}^{2}}{{c}_{33}} ) {ɛ}_{xxi} \qquad [ 9 ]$$

where d₃₁ is a piezoelectric constant, c₁₁, c₁₂, c₁₃, and c₃₃ are elastic stiffness constants. εₓₓᵢ is the effective strain in the i-th layer as calculated above.
The total polarization field Pₜᵢ leads to an electric field Eⱼ, and the electric displacement Dᵢⱼ can be determined as follows when εᵢⱼ is the permittivity tensor.

Dᵢⱼ=εᵢⱼEⱼ+Pₜᵢ [10]

In some embodiments, the internal electric field in the i-th layer of laminated structure 100 can be determined as follow.

$${E}_{i} = \frac{{\sum }_{k} \text{?} ( {d}_{k} P \text{?} / {ɛ}_{k} ) - P \text{?} \sum \text{?} {d}_{k} / {ɛ}_{k}}{{ɛ}_{i} \sum \text{?} {d}_{k} / ɛ \text{?}} \\ \text{?} \text{indicates text missing or illegible when filed} \qquad [ 11 ]$$

where εₖ is a dielectric constant in the k-th layer. Further, in laminated structure 100, a periodic boundary condition as described below can be applied.

$$\sum \text{?} d \text{?} E \text{?} = 0 \\ \text{?} \text{indicates text missing or illegible when filed} \qquad [ 12 ]$$

By solving Equations [8]-[11] using the boundary condition expressed in Equation [12], the internal electric field Eᵢ in the i-th layer when the i-th layer has a strain εₓₓᵢ and the thickness Dᵢ can be computed. The strain [symbol] εₖₘ [symbol] calculated from Equations [6]-[7] may be used for the strain εₓₓᵢ and the thickness which is used in Equations [6]-[7] may be used as the thickness dᵢ.

The internal electric field Eᵢ in active layer 164 may be calculated for various laminated structures 100, by using the strains for corresponding laminated structure 100, which are calculated from Equations [6]-[7]. Therefore, laminated structure 100 which includes active layer 164 with a minimum internal electric field may be selected to design an optoelectronic device with improved optical gain. Further, a thickness and a composition of each layer, which are assumed for calculating Equations [6]-[7], may be employed to design laminated structure 100 to include light emitting layer 160 thereby reducing the internal electric field.

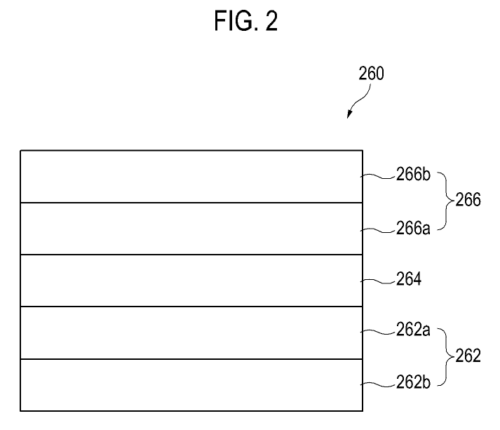

FIG. 2 shows an illustrative embodiment of a light emitting layer 260 having a stepped barrier structure. As depicted, light emitting layer 260 may include a first cladding layer 262, an active layer 264, and a second cladding layer 266. In some embodiments these layers are stacked in sequence.

Active layer 264 may include a nitride based semiconductor. The nitride based semiconductor may include indium, gallium, or nitrogen with a composition of InₓGa₁₋ₓN (x≦1). The indium concentration, x, in InₓGa₁₋ₓN may be changed depending on the usage or application of the laminated structure, e.g., in a light emitting diode (LED), in a laser diode (LD), etc. For example, x may be in the range of about 0.34≦x≦0.47 for a visible blue light emission application or about 0≦x≦0.19 for an ultraviolet light emission application. In general, x may be in the range of about 0≦x≦0.3 for a light emitting device.

In some embodiments, first and second cladding layers 262 and 266 may be an n-type or a p-type cladding layer, including indium, gallium, or nitrogen. First and second cladding layers 262 and 266 may be doped with different types of dopants. For example, if first cladding layer 262 is doped with at least one n-type dopant selected from Si, Ge, or Sn, second cladding layer 266 is doped with at least one p-type dopant selected from Zn, Mg, Ca, or Be, and vice versa.

First cladding layer 262 of light emitting layer 260 may include a first barrier layer 262a and a second barrier layer 262b which is provided under first barrier layer 262a. Second cladding layer 266 of light emitting layer 260 may include a first barrier layer 266a and a second barrier layer 266b which is provided above first barrier layer 266a. In some embodiments, active layer 264 may be positioned between first barrier layers 262a and 266a.

First and second barrier layers 262a and 262b and active layer 264 may have compositions conducive to forming a step-down barrier structure where the energy band-gap of first barrier layer 262a is smaller than that of second barrier layer 262b and wider than that of active layer 264. In some embodiments, active layer 264 and first and second barrier layers 262a and 262b may include indium, gallium, or nitrogen, having compositions of InₓGa₁₋ₓN, In_{ya}Ga_{1-ya}N (yₐ≦1) and In_{yb}Ga_{1-yb}N (y_{b}≦1), respectively, where indium concentration yₐ is larger than indium concentration y_{b} and smaller than indium concentration x. In other embodiments, second barrier layer 262b does not include indium so that the indium concentration y_{b} of second barrier layer 262b may be “0.”

First and second barrier layers 266a and 266b and active layer 264 may have compositions to form a step-up barrier structure where the energy band-gap of first barrier layer 266a is smaller than that of second barrier layer 266b and wider than that of active layer 264. In some embodiments, active layer 264 and first and second barrier layers 266a and 266b may include indium, gallium, or nitrogen, having compositions of InₓGa₁₋ₓN, In_{za}N (zₐ≦1) and In_{zb}Ga_{1-zb}N (z_{b}≦1), respectively, where the indium concentration zₐ is larger than the indium concentration z_{b} and smaller than the indium concentration x of active layer 264. In some embodiments, second barrier layer 266b may not include indium so that the indium concentration z_{b} of second barrier layer 266b may be “0.”

The above described stepped barrier structure of light emitting layer 260 may reduce the strain in active layer 264 and first and second cladding layers 262 and 266 so that the internal electric field in active layer 264 may be reduced. Further, an optical device which employs light emitting layer 260 may have enhanced optical gain.

The stepped barrier structure may be further designed to improve internal electric reduction. In some embodiments, a composition of each layer included in light emitting layer 260 may be selected to minimize an internal electric field in active layer 264. For example, a composition or a thickness of first barrier layers 262a and 266a may be selected to reduce the internal electric field while active layer 264 and second barrier layers 262b and 266b may have compositions and thicknesses which were made without considering the internal electric field generated. However, it should be appreciated that the composition and thicknesses for other layers (e.g., second barrier layers 262b and 266b or active layer 264) may be selected to reduce the internal electric filed.

As mentioned above, Equations [6]-[7] may be used to calculate the strain in each layer of light emitting layer 260. Equations [6]-[7] may provide as a solution the strain in each position of each layer when a dimension (i.e., an area and a thickness) and/or a composition of each layer are given. In some embodiments, therefore, the specific values for the thickness and area of each layer (i.e., first barrier layers 262a and 266a, second barrier layers 262b and 266b, and active layer 264) may be specified to calculate the strain in each position of each layer. In some embodiments, a composition of each layer may be specified to calculate the strain in each position of each layer.

With specific values for the thickness and area of each layer, a strain in each position of a layer may be computed from Equations [6]-[7]. Further, a strain in each layer may be obtained by averaging the strains in each layer.

In some embodiments, Equations [8]-[12] may be used to calculate the internal electric field in active layer 264. The above strains calculated from Equations [6]-[7] may be used to solve Equations [8]-[12] so that the internal electric field in active layer 264 can be computed. In some embodiments, various internal electric fields for various layers of light emitting layer 260 may be computed from Equations [8]-[12] and based on the calculated strains for various layers of light emitting layer 260. The computed various internal electric fields can be used to determine the strain which generates a minimum internal electric field.

Table 1 shows the calculation results of Equations [6]-[7] and Equations [8]-[12] for various thicknesses of first barrier layers 262a and 266a. The calculations are based on the assumption that active layer 264 has a thickness of about 3 nm and a composition of In_{0.2}Ga_{0.8}N, second barrier layer 262b has a thickness of about 6 nm and a composition of GaN, and first barrier layer 262a has a composition of In_{0.05}Ga_{0.95}N. Further, it is assumed that first and second cladding layers 262 and 266 are symmetrical with respect to active layer 264. Therefore, it is assumed that first barrier layer 266a has the same thickness and composition as first barrier layer 262a, and second barrier layer 266b has the same thickness and composition as second barrier layer 262b.

The term “strain in cladding layer” used in Table 1 and used in Tables 2-6 refers to the strain in each of first and second cladding layers 262 and 266. In Table 1, first and second cladding layers 262 and 266 have the same strain due to the assumption that first and second cladding layers 262 and 266 are symmetrical with respect to active layer 264.

TABLE 1

| | first barrier layer's | | |
|---|---|---|---|
| | thickness | | |
| | 2 nm | 4 nm | 6 nm |
| Strain in active layer (%) | −2.04 | −2.021 | −1.97 |
| Strain in cladding layer | −0.113 | −0.07 | −0.04 |
| (%) | | | |
| Internal electric field | 2.875 | 2.812 | 2.76 |
| in active layer (MV/cm) | | | |

Referring to Table 1, active layer 264 has a small internal electric field of 2.76 MV/cm when a strain in active layer 264 is −1.97% and strains in first and second cladding layers 262 and 266 are −0.04%. Therefore, a thickness of 6 nm can be selected for first barrier layers 262a and 266a to reduce the internal electric field. Further, the data in Table 1 shows that the internal electric field increases as the thickness of first barrier layers 262a and 266a increases. Therefore, the thickness of first barrier layers 262a and 266a may be increased within the size limit of the application.

Table 2 shows the calculation results of Equations [6]-[7] and Equations [8]-[12] for various compositions of first barrier layers 262a and 266a. The calculations are based on the assumption that active layer 264 has a thickness of about 3 nm and a composition of In_{0.2}Ga_{0.8}N, second barrier layer 262b has a thickness of about 6 nm and a composition of GaN, and first barrier layer 262a has a thickness of about 6 nm. Further, it is assumed that first and second cladding layers 262 and 266 are symmetrical with respect to active layer 264. Therefore, it is assumed that first barrier layer 266a has the same thickness and composition as first barrier layer 262a, and second barrier layer 266b has the same thickness and composition as second barrier layer 262b.

As mentioned above, in Table 2, first and second cladding layers 262 and 266 have the same strain due to the assumption that first and second cladding layers 262 and 266 are symmetrical with respect to active layer 264.

TABLE 2

| | first barrier layer's | | |
|---|---|---|---|
| | composition | | |
| | GaN | In_{0.025}Ga_{0.975}N | In_{0.05}Ga_{0.95}N |
| Strain in active layer (%) | −2.09 | −2.01 | −1.72 |
| Strain in cladding layer | 0.14 | −0.08 | −0.39 |
| (%) | | | |
| Internal electric field | 3.01 | 2.9 | 2.79 |
| in active layer (MV/cm) | | | |

As indicated in Table 2, active layer 264 has a smaller internal electric field of 2.79 MV/cm when a strain in active layer 264 is −1.72% and strains in first and second cladding layers 262 and 266 are −0.39%. Therefore, In_{0.05}Ga_{0.95}N can be selected as a composition for first barrier layers 262a and 266a to reduce the internal electric field.

The data in Tables 1 and 2 is for a light emitting layer, such as light emitting layer 260, which is not in contact with the other layers so that the strains and the internal electric field may change when the light emitting layer is in contact with one or more of the other layers, such as substrate 120 or buffer layer 140 in FIG. 1, and the electrode pad is provided over the light emitting layer.

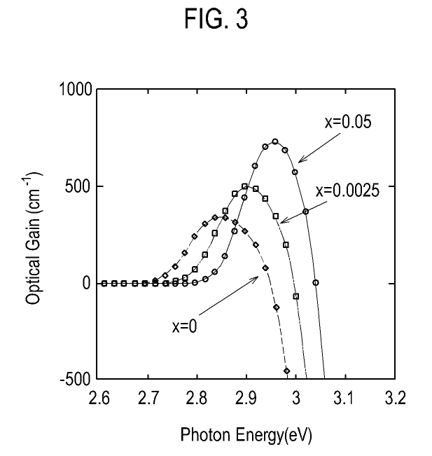

FIG. 3 is a graph showing optical gains for various compositions of first barrier layers 262a and 266a in FIG. 2, which are calculated based on the calculation results in Table 1. Referring to FIG. 3, maximum optical gain increases as the indium concentrations x of first barrier layers 262a and 266a increase. An indium concentration x of “0” refers to a normal barrier structure where first barrier layers 262a and 266a do not exist. As shown in FIG. 3, the maximum optical gain of light emitting layer 260 with the stepped barrier structure is larger than that with the normal barrier structure. Further, light emitting layer 260 has a larger maximum optical gain when it includes first barrier layers 262a and 266a with the indium concentration x of 0.05 rather than 0.025. These are consistent with the results of Table 2. Accordingly, the graph in FIG. 3 indicates that the composition of first barrier layers 262a and 266a reduce the internal electric field, and may be employed to improve the optical gain.

Tables 1 and 2, and FIG. 3 merely represent certain illustrative embodiments and are not to be considered to limit the scope of the disclosure. The materials constituting light emitting layer 260 may be changed, and the dimensions thereof may also be changed.

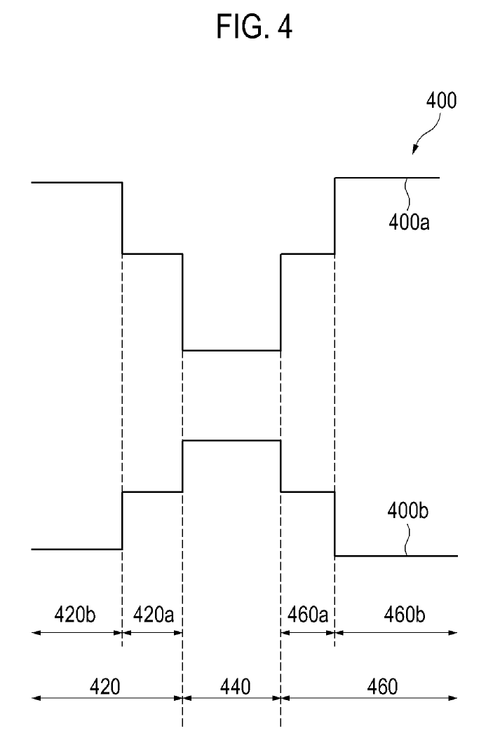

FIG. 4 is an energy band diagram 400 schematically describing a conduction band 400a and a valence band 400b of light emitting layer 260 having the stepped barrier structure shown in FIG. 2. Reference numerals 420, 440, 460 in FIG. 4 represent the regions of first cladding layer 262, active layer 264, and second cladding layer 266, respectively. Reference numerals 420a and 420b represent regions of first barrier layer 262a and second barrier layer 262b of first cladding layer 262, respectively. Reference numerals 460a and 460b represent regions of first barrier layer 266a and second barrier layer 266b of second cladding layer 266, respectively. FIG. 4 shows an illustrative embodiment only and is not intended to be limiting in any way. For example, an energy band may have a transitional region between first barrier layers 262a, 266a and second barrier layers 262b and 266b.

Referring to FIG. 4, the energy band-gaps of first and second cladding layers 262 and 266 are wider than that of active layer 264 so that a quantum well for confining electrons and holes is formed in active layer 264. That is, the energy levels of first and second cladding layers 262 and 266, which are higher than that of active layer 264, do not allow the electrons and the holes in active layer 264 to be diffused to first and second cladding layers 262 and 266 while allowing the electrons or the holes in first and second cladding layers 262 and 266 to be diffused to active layer 264. As a result, the electrons and the holes can be confined within active layer 264 (i.e., a quantum well) without diffusing to other layers.

Referring to FIG. 4, first and second barrier layers 262a and 262b have different band-gaps to form the step-down barrier structure where the band-gap of second barrier layer 262b is wider than that of first barrier layer 262a, while first and second barrier layers 266a and 266b have different band-gaps to form the step-up barrier structure where the band-gap of second barrier layer 266b is wider than that of first barrier layer 266a. FIG. 4 describes some embodiments of light emitting layer 160 with a stepped barrier structure which has a symmetrical energy band gap diagram where first barrier layers 262a and 266a have the same energy band gap, and second barrier layers 262b and 266b have the same energy band gap. In other embodiments, however, first barrier layer 262a may have a different energy band gap than first barrier layer 266a, and second barrier layer 262b may have a different energy band gap than second barrier layer 266b. It should be appreciated that the energy band diagram may be modified in various ways.

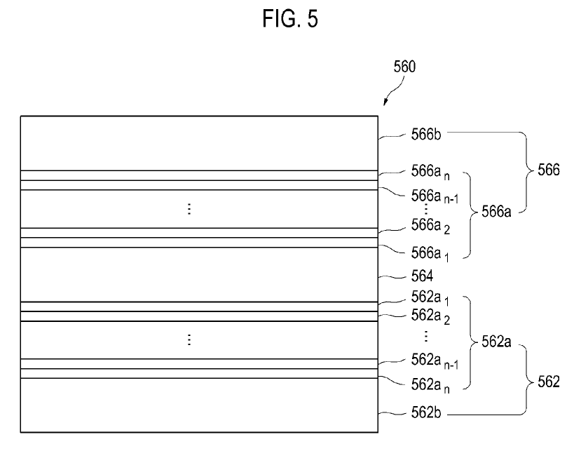

FIG. 5 illustrates another embodiment of a light emitting layer 560 having a graded barrier structure, which is further described below. As depicted, light emitting layer 560 may include a first cladding layer 562, an active layer 564, and a second cladding layer 566. In some embodiments, these layers are stacked in sequence.

In some embodiments, active layer 564 may include a nitride based semiconductor. The nitride based semiconductor may include indium, gallium, or nitrogen with a composition of Inₓga₁₋ₓN (x≦1). The indium concentration, x, in InₓGa₁₋ₓN may be changed depending on the usage or application of the laminated structure, e.g., in a light emitting diode (LED), in a laser diode (LD), etc. For example, x may be in the range of about 0.34≦x≦0.47 for a visible blue light emission application or about 0≦x≦0.19 for an ultraviolet light emission application. In general, x may be in the range of about 0≦x≦0.3 for a light emitting device.

First and second cladding layers 562 and 566 may be an n-type or a p-type cladding layer, including indium, gallium, or nitrogen. First and second cladding layers 562 and 566 may be doped with different types of dopants. For example, if first cladding layer 562 is doped with at least one n-type dopant selected from Si, Ge, or Sn, second cladding layer 566 is doped with at least one p-type dopant selected from Zn, Mg, Ca, or Be, and vice versa.

First cladding layer 562 of light emitting layer 560 may include a first barrier layer 562a and a second barrier layer 562b which is under first barrier layer 562a. First barrier layer 562a may be divided into barrier sub-layers 562aₙ to 562a₁ (n>1) which are stacked over second barrier layer 562b in sequence. That is, barrier sub-layer 562aₙ is stacked on second barrier layer 562b first, and then barrier sub-layers 562ₐₙ₋₁ to 562a₁ are stacked or piled up over barrier sub-layer 562aₙ so that barrier sub-layers 562aₙ₋₁ to 562a₁ are positioned on top of first barrier layer 562a. Second cladding layer 566 of light emitting layer 560 may include a first barrier layer 566a and a second barrier layer 566b which is above first barrier layer 566a. First barrier layer 566a may be divided into barrier sub-layers 566a₁ to 566aₙ (n>1) which are stacked or piled up over active layer 564 in sequence. In some embodiments, first stacked barrier sub-layer 566a₁ may be provided right above active layer 564, and barrier sub-layers 566a₂ to 566aₙ may be stacked sequentially thereon. In other embodiments, active layer 564 may be positioned between the last stacked barrier sub-layer 562a₁ of first cladding layer 562 and first stacked barrier sub-layer 566a₁ of second cladding layer 566.

First and second barrier layers 562a and 562b and active layer 564 may have different compositions such that an energy band-gap of first barrier layer 562a is not less than that of active layer 564, and is not greater than that of second barrier layer 562b. In some embodiments, active layer 564 and first and second barrier layers 562a and 562b may include indium, gallium, or nitrogen, having compositions of InₓGa₁₋ₓN, In_{ya}Ga_{1-ya}N (yₐ≦1) and In_{yb}Ga_{1-yb}N (y_{b}≦1), respectively, where an indium concentration yₐ is not less than an indium concentration y_{b} and not greater than an indium concentration x.

Barrier sub-layers 562a₁ to 562aₙ may have a different indium composition to form a graded down structure where the energy band-gaps of barrier sub-layers 562a₁ to 562aₙ are gradually decreased from that of barrier sub-layer 562aₙ to that of barrier sub-layer 562a₁, which is further described below. In some embodiments, barrier sub-layers 562a₁ to 562aₙ may include indium, gallium, or nitrogen, having compositions of In_{yai}Ga_{1-yai}N (yₐᵢ≦1) while active layer 564 has a composition of InₓGa₁₋ₓN. For example, an i-th barrier sub-layer 562aᵢ may have an indium concentration yₐᵢ which is smaller than that of an (i−1)-th barrier sub-layer 562aᵢ₋₁ which is provided above the i-th barrier sub-layer 562aᵢ, and larger than that of an (i+1)-th barrier sub-layer 562aᵢ₊₁ which is provided under the i-th barrier sub-layer 562aᵢ. In other embodiments, last stacked barrier sub-layer 562a₁ which may be below active layer 564 may have the largest indium composition yₐ₁ among the indium compositions yₐ₁ to yₐₙ of the other barrier sub-layers 562a₁ to 562aₙ. In an alternate embodiment, the largest indium composition among the indium compositions yₐ₁ to yₐₙ is not greater than the indium composition x of active layer 564. First stacked barrier sub-layer 562aₙ, which is stacked over second stacked barrier sub-layer 562b, may have a smaller indium composition yₙ than the indium compositions yₐ₁ to yₐ₍ₙ₋₁₎ of other barrier layers 562a₁ to 562aₙ₋₁. In other embodiments, first stacked barrier layer 562aₙ may not include indium so that the indium concentration yₐₙ of first stacked barrier layer 562aₙ may be “0.”

First and second barrier layers 566a and 566b and active layer 564 may have different compositions such that the energy band-gap of first barrier layer 566a is not less than that of active layer 564 and is not greater than that of second barrier layer 566b. In some embodiments, active layer 564 and first and second barrier layers 566a and 566b may include indium, gallium, or nitrogen, having compositions of InₓGa₁₋ₓN, In_{za}Ga_{1-za}N (zₐ≦1) and In_{zb}Ga_{1-zb}N (z_{b}≦1), respectively, where the indium concentration zₐ is not less than the indium concentration z_{b} and not greater than the indium concentration x.

Barrier sub-layers 566a₁ to 566aₙ may have a different indium composition to form a graded up structure where the energy band-gaps of barrier sub-layers 566a₁ to 566aₙ are gradually increased from that of barrier sub-layer 566a₁ to that of barrier sub-layer 566aₙ, which is further described below. In some embodiments, barrier sub-layers 566a₁ to 566aₙ may include indium, gallium, or nitrogen, having compositions of In_{zai}Ga_{1-zai}N (zₐᵢ≦1) while active layer 564 has a composition of InₓGa₁₋ₓN. For example, an i-th barrier sub-layer 566aᵢ may have an indium concentration zₐᵢ which is smaller than that of an (i−1)-th barrier sub-layer 566aᵢ₋₁ provided above the i-th barrier sub-layer 566aᵢ, and larger than that of an (i+1)-th barrier sub-layer 566aᵢ₊₁ provided under the i-th barrier sub-layer 566aᵢ. In some embodiments, last stacked barrier sub-layer 566aₙ may have the largest indium composition zₐₙ among the indium compositions zₐ₁ to Zₐ₍ₙ₋₁₎ of the other barrier sub-layers 566a₁ to 566aₙ₋₁. In other embodiments, the largest indium composition among the indium compositions z₁ to zₐₙ is not greater than the indium composition x of active layer 564. First stacked barrier sub-layer 566a₁, which is stacked over active layer 564, may have a smaller indium composition zₐ₁ than the indium compositions zₐ₂ to zₐₙ of the other barrier sub-layers 566a₂ to 566aₙ. In an alternate embodiment, first stacked barrier layer 566a₁ may not include indium so that the indium concentration zₐ₁ of first stacked barrier layer 566a₁ may be “0.”

The above graded barrier structure may be further designed to improve internal electric reduction. In some embodiments, a composition or a thickness of each layer included in light emitting layer 560 may be selected to minimize the internal electric field in active layer 564. For example, a composition or a thickness of first barrier layers 562a and 566a may be selected to reduce the internal electric field while active layer 564 and second barrier layers 562b and 566b may have predetermined compositions and thicknesses without regard to the internal electric field. That is, each barrier sub-layer 562a₁ to 562aₙ of first barrier layer 562a and each barrier sub-layer 566a₁ to 566aₙ of first barrier layer 566a may be selected to have compositions and thicknesses to reduce the internal electric field in the active layer. However, it should be appreciated that the compositions and thicknesses for other layers (e.g., second barrier layers 562b and 566b or active layer 564) may be selected to reduce the internal electric filed.

As mentioned above, Equations [6]-[7] may be used to calculate the strain in each layer of light emitting layer 560. Equations [6]-[7] may provide as a solution the strain in each position of each layer when a dimension (i.e., an area and a thickness) and/or a composition of each layer are given. In some embodiments, the strain for each position of each layer (i.e., first barrier layers 562a and 566a, second barrier layers 562b and 566b, and active layer 564) may be calculated from Equations [6]-[7] based a thickness, area, and composition of each layer (i.e., first barrier layers 562a and 566a, second barrier layers 562b and 566b, and active layer 564). Further, in some embodiments, the strain for each position of each barrier sub-layer 562a₁ to 562aₙ and 566a₁ to 566aₙ may be calculated from Equations [6]-[7] based on the thickness, area, and composition of each layer (i.e., each barrier sub-layer 562a₁ to 562aₙ and 566a₁ to 566aₙ of first barrier layers 562a and 566a, second barrier layers 562b and 566b, and active layer 564). With specific values for the thickness and area of each layer, a strain in each position of a layer may be computed from Equations [6]-[7], and a strain in a layer may be obtained by averaging the strains at the positions in the layer.

In some embodiments, Equations [8]-[12] may be used to calculate the internal electric field in active layer 564. The above strains calculated from Equations [6]-[7] may be used to solve Equations [8]-[12] so that the internal electric field in active layer 564 can be computed. In some embodiments, various internal electric fields according to the strains may be computed from Equations [8]-[12], and can be used to determine the strain which generates a minimum internal electric field.

Table 3 shows the calculation results of Equations [6]-[7] and Equations [8]-[12] for various thicknesses of first barrier layers 562a and 566a. The calculations are based on the assumption that active layer 564 has a thickness of about 3 nm and a composition of In_{0.2}Ga_{0.8}N, second barrier layer 562b has a thickness of about 6 nm and a composition of GaN. Further, it is assumed that first barrier layer 562a includes barrier sub-layers 562a₁ to 562a₁₀ which have compositions of In_{0.19}Ga_{0.81}N, In_{0.185}Ga_{0.815}N, In_{0.17}Ga_{0.83}N, In_{0.15}Ga_{0.985}N, In_{0.11}Ga_{0.89}N, In_{0.09}Ga_{0.91}N, In_{0.05}Ga_{0.95}N, In_{0.03}Ga_{0.97}N, In_{0.015}Ga_{0.85}N, and In_{0.01}Ga_{0.99}N, respectively, and have the same thickness. Further, it is assumed that first and second cladding layer 562 and 566 are symmetrical with respect to active layer 564. Therefore, it is assumed second barrier layer 566b has the same thickness and same composition as second barrier layer 562b, first barrier layer 566a has barrier sub-layers 566a₁ to 566a10 which have the same compositions and thicknesses as barrier sub-layers 562a₁₀ to 562a₁, respectively.

In Table 3, first and second cladding layers 562 and 566 have the same strain due to the assumption that first and second cladding layers 562 and 566 are symmetrical with respect to active layer 564.

TABLE 3

| | first barrier layer's | | |
|---|---|---|---|
| | thickness | | |
| | 2 nm | 4 nm | 6 nm |
| Strain in active layer (%) | −2.01 | −1.98 | −1.86 |
| Strain in cladding layer | −0.102 | −0.064 | −0.023 |
| (%) | | | |
| Internal electric field | 2.589 | 2.512 | 2.487 |
| in active layer (MV/cm) | | | |

Referring to Table 3, when a strain in active layer 564 is −1.86% and strains in first and second cladding layers 562 and 566 are −0.023%, active layer 564 has a small internal electric field of 2.487 MV/cm. Therefore, a thickness of 6 nm can be selected for first barrier layers 562a and 566a to reduce the internal electric field. Further, the data in Table 3 shows that the internal electric field increases as the thickness of first barrier layers 562a and 566a increases. Therefore, the thickness of first barrier layers 562a and 566a may be increased.

Table 4 shows the calculation results of Equations [6]-[7] and Equations [8]-[12] for various compositions of first barrier layers 562a and 566a. Specifically, Equations [6]-[7] and Equations [8]-[12] are calculated for light emitting layers 560 where barrier sub-layers 562a₁₀ to 562a₁ and 566a₁ to 566a₁₀ have indium concentrations selected from three groups of ranges (i.e., 0 to 0.19, 0.025 to 0.19 and 0.05 to 0.19). The calculations are based on the assumption that active layer 564 has a thickness of 3 nm and a composition of In_{0.02}Ga_{0.8}N, second barrier layer 562b has a thickness of 6 nm and a composition of GaN, and each barrier sub-layer 562a₁ to 562a₁₀ has a thickness of 0.6 nm. Further, it is assumed that first and second cladding layers 562 and 566 are symmetrical with respect to active layer 564. Therefore, it is assumed second barrier layer 566b has the same thickness and the same composition as second barrier layer 562b. Further, it is assumed that first barrier layer 566a includes barrier sub-layers 566a₁ to 566a₁₀ which have the same compositions and thicknesses as barrier sub-layers 562a₁₀ to 562a₁, respectively.

As mentioned above, in Table 4, “strain in cladding layer” refers to the strain in each of first and second cladding layers 562 and 566. Nevertheless, first and second cladding layers 562 and 566 have the same strain due to the assumption that first and second cladding layers 562 and 566 are symmetrical with respect to active layer 564.

TABLE 4

| | first barrier layer's | | |
|---|---|---|---|
| | composition | | |
| | (indium concentration | | |
| | range) | | |
| | 0-0.19 | 0.025-0.19 | 0.05-0.19 |
| Strain in active layer (%) | −2.04 | −1.96 | −1.81 |
| Strain in cladding layer | −0.108 | −0.061 | −0.018 |
| (%) | | | |
| Internal electric field | 2.624 | 2.509 | 2.456 |
| in active layer (MV/cm) | | | |

As indicated in Table 4, when a strain in active layer 564 is −1.81% and strains in first and second cladding layers 562 and 566 are −0.018%, active layer 564 has a smaller internal electric field of 2.456 MV/cm. Therefore, the range from about 0.05 to about 0.19 can be selected as an indium concentration range for barrier sub-layers 562a₁, to 562aₙ of first barrier layer 562a and for barrier sub-layers 566a₁ to 566aₙ of first barrier layer 566a to reduce the internal electric field.

The data in Tables 3 and 4 is for a light emitting layer, such as light emitting layer 560, which is not in contact with the other layers so that the strains and the internal electric field may be changed when the light emitting layer is in contact with one or more of the other layers, such as substrate 120 or buffer layer 140 in FIG. 1, and the electrode pad is provided over the light emitting layer.

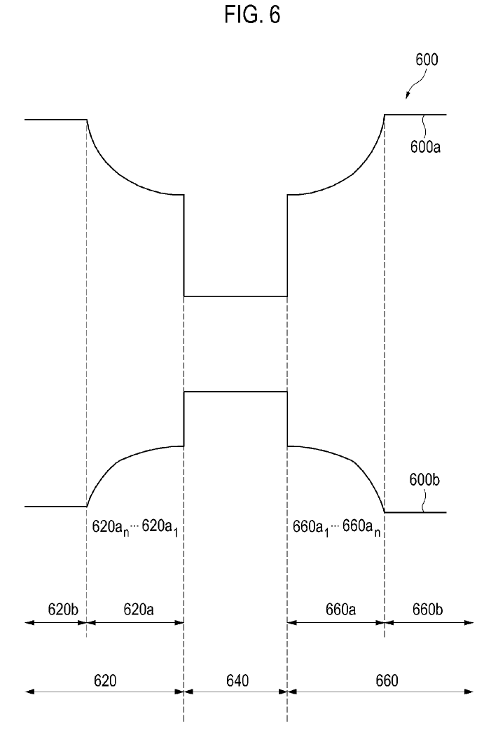

FIG. 6 is an energy band diagram 600 that schematically describes a conduction band 600a and a valence band 600b of light emitting layer 560 having a graded barrier structure shown in FIG. 5. Reference numerals 620, 640 and 660 in FIG. 6 represent the regions of first cladding layer 562, active layer 564, and second cladding layer 566, respectively Reference numerals 620a and 620b represent the regions of first barrier layer 562a and second barrier layer 562b, respectively. Reference numerals 660a and 660b represent the regions of first barrier layer 566a and second barrier layer 566b, respectively. Reference numerals 620a₁ to 620aₙ represent the regions of barrier sub-layers 562a₁ to 562aₙ of first barrier layer 562a, respectively, while reference numerals 660a₁ to 660aₙ represent the regions of barrier sub-layers 566a₁ to 566aₙ of first barrier layer 566a, respectively.

Referring to FIG. 6, the band gap of second barrier layer 562b of first cladding layer 562 may be wider than that of active layer 564, and first barrier layer 562a may have an energy band gap gradually decreasing from the energy band gap of second barrier layer 562b to the energy band gap of active layer 564. For example, the band-gap energy levels of barrier sub-layers 562a₁ to 562aₙ of first barrier layer 562a may decrease step by step to the band-gap energy of active layer 564. In some embodiments, an energy band gap difference between the band-gap energy levels of barrier sub-layers 562a₁ to 562aₙ and the energy band gap level of active layer 564 may be inversely proportional to a distance between corresponding second barrier sub-layers 562a₁ to 562aₙ and active layer 564. In other embodiments, the band gap differences between adjacent barrier sub-layers 562aᵢ and 562aᵢ₊₁ may be equal, but in alternate embodiments they may not be equal. In other embodiments, only some of barrier sub-layers 562a₁ to 562aₙ may have the same band gap differences. In another embodiment, the band gap differences between adjacent barrier sub-layers 562aᵢ and 562aᵢ₊₁ may be different.

As discussed above, the energy band gap of first and second barrier layers 562a and 562b, and of barrier sub-layers 562a₁ to 562aₙ may vary according to the compositions thereof Therefore, barrier sub-layers 562a₁ to 562aₙ may have different compositions to form the graded down structure. For example, when first or second barrier layers 562a or 562b includes indium, gallium, or nitrogen, the band gap of first or second barrier layers 562a or 562b may become wider as the indium concentration increases. In some embodiments, barrier sub-layers 562a₁ to 562aₙ may have a greater indium concentration y as “i” increases to form the graded down structure.

The graded up structure of first barrier layer 566a may be similar with first barrier layer 562a. Referring to FIG. 6, the energy band gap of second barrier layer 566b is wider than that of active layer 564, and the energy band gap of first barrier layer 566a may gradually increase from that of active layer 564 to that of second barrier layer 566b. In some embodiments, the band gap energy levels of barrier sub-layers 566a₁ to 566aₙ of first barrier layer 566a may increase step by step to the band gap energy of active layer 564. In other embodiments, an energy band gap difference between the band-gap energy levels of barrier sub-layers 566a₁ to 566aₙ and the energy band gap level of active layer 564 may be proportional to a distance between corresponding second barrier sub-layers 566a₁ to 566aₙ and active layer 564. In some embodiments, the band gap differences between the adjacent barrier sub-layers 566aᵢ and 566aᵢ₊₁ may be equal. In other embodiments, only some of barrier sub-layers 566a₁ to 566aₙ may have the same band gap differences. In still other embodiments, the band gap differences between adjacent barrier sub-layers 566aᵢ and 566aᵢ₊₁ may be different.

In some embodiments, barrier sub-layers 566a₁ to 566aₙ may have different compositions to form the graded up structure. For example, when first and second barrier layers 566a and 566b include indium, gallium, or nitrogen, barrier sub-layers 566a₁ to 566aₙ may have a greater indium concentration y as “i” increases to form the graded up structure. FIG. 6 shows that light emitting layer 560 with the graded barrier structure has a symmetrical energy band gap diagram, although in other embodiments the energy band gap is not symmetrical. It should be appreciated that the energy band diagram may be modified in various ways.

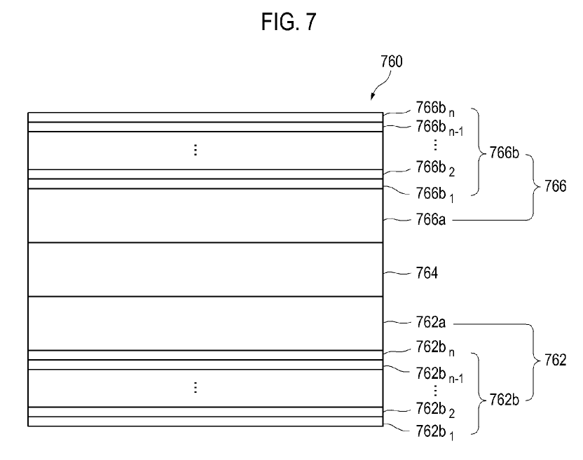

FIG. 7 illustrates another embodiment of a light emitting layer 760 having a multiple barrier structure where at least one quantum well is provided as a barrier layer. As depicted, light emitting layer 760 may include a first cladding layer 762, an active layer 764, and a second cladding layer 766. In some embodiments, these layers may be stacked in sequence.

In other embodiments, active layer 764 may include a nitride based semiconductor. The nitride based semiconductor may include indium, gallium, or nitrogen with a composition of InₓGa₁₋ₓN (x≦1). The indium concentration, x, in InₓGa₁₋ₓN may be changed depending on the usage or application of the laminated structure, e.g., in a light emitting diode (LED), in a laser diode (LD), etc. For example, x may be in the range of about 0.34≦x≦0.47 for a visible blue light emission application or about 0≦x≦0.19 for an ultraviolet light emission application. In general, x may be in the range of about 0≦x≦0.3 for a light emitting device.

First and second cladding layers 762 and 766 may be an n-type or a p-type cladding layer, including indium, gallium, or nitrogen. First and second cladding layers 762 and 766 may be doped with different types of dopants. For example, if first cladding layer 762 is doped with at least one n-type dopant selected from Si, Ge, or Sn, second cladding layer 766 is doped with at least one p-type dopant selected from Zn, Mg, Ca, or Be, and vice versa.

First cladding layer 762 may include a first barrier layer 762a and a second barrier layer 762b which is provided under first barrier layer 762a. Second barrier layer 762b may include barrier sub-layers 762b₁ to 762bₙ (n>2). In some embodiments these layers are stacked in sequence to form a multiple quantum well structure. Second cladding layer 766 of light emitting layer 760 may include a first barrier layer 766a and a second barrier layer 766b which are stacked over first barrier layer 766a. Second barrier layer 766b may include barrier sub-layers 766b₁ to 766bₙ (n>2) which are stacked in sequence to form a multiple quantum well structure. In some embodiments, active layer 764 may be positioned between first barrier layer 762a of first cladding layer 762 and first barrier layer 766a of second cladding layer 766.

Some of barrier sub-layers 762b₁ to 762bₙ may have a different composition from the other barrier sub-layers 762b₁ to 762bₙ to form at least one quantum well. In some embodiments, active layer 764 and first and second barrier layers 762a and 762b may include indium, gallium, or nitrogen, having a compositions of InₓGa₁₋ₓN, In_{ya}Ga_{1-ya}N (yₐ≦1) and In_{yb}Ga_{1-yb}N (y_{b}≦1), respectively, and barrier sub-layers 762b₁ to 762bₙ may include indium, gallium, or nitrogen, with a composition represented as In_{ybi}Ga_{1-ybi}N (y_{bi}≦1). In some embodiments, the indium concentration yₐ of first barrier layer 762a may be larger than the indium concentration x of active layer 764, and some of the indium concentrations y_{bi} of second barrier layer 762bᵢ may be smaller than the indium concentration yₐ. In other embodiments, two adjacent barrier sub-layers 762bᵢ and 762bᵢ₊₁ may have different indium compositions yᵢ while (i−1)-th and (i+1)-th barrier sub-layers 762bᵢ₋₁ and 762bᵢ₊₁, which are provided under and above i-th barrier sub-layers 762bᵢ, respectively, may have substantially the same indium composition. For example, the indium composition y_{bi} of i-th barrier sub-layers 762bᵢ may be smaller than that of the (i−1)-th and (i+1)-th barrier sub-layer 762bᵢ₋₁ and 762bᵢ₊₁. In some embodiments, barrier sub-layers 762bᵢ and 762bᵢ₊₁ which have different compositions may be stacked in turn.

Barrier sub-layers 766b₁ to 766bₙ may have a similar structure with barrier sub-layers 762b₁ to 762bₙ. In some embodiments, light emitting layer 760 may have a symmetrical structure where first cladding layer 762 includes the same number of barrier sub-layers 766b₁ to 766bₙ as barrier sub-layers 762b₁ to 762bₙ, and barrier sub-layers 766b₁ to 766bₙ are formed with the same composition as corresponding barrier sub-layers 762b₁ to 762bₙ. In other embodiments, light emitting layer 760 has a non-symmetrical structure where barrier sub-layers 766b₁ to 766bₙ and barrier sub-layers 762b₁ to 762bₙ are not identical. For example, first cladding layer 762 and second cladding layer 766 may include a different number of barrier sub-layers.

The above multiple barrier structure may be further designed to improve internal electric field reduction. In some embodiments, a composition of each layer included in light emitting layer 760 may be selected to minimize the internal electric field in active layer 764. For example, a composition of second barrier layers 762b and 766b where a multiple barrier structure is provided may be selected to reduce the internal electric field while active layer 764 and first barrier layers 762a and 766a have compositions and thicknesses which were selected without regard to the internal electric field. That is, each barrier sub-layer 762b₁ to 762bₙ of second barrier layer 762b and each barrier sub-layer 766b₁ to 766bₙ of second barrier layer 766b may be selected to have compositions to reduce the internal electric field in active layer 764. In other embodiments, a thickness of each layer included in light emitting layer 760 may be selected to minimize the internal electric field in active layer 764. For example, a thickness of first barrier layers 762a and 766a may be selected to reduce the internal electric field while active layer 764 and first barrier layers 762a and 766a have predetermined compositions and thicknesses. However, it should be appreciated that the composition and thicknesses for other layers (e.g., first barrier layers 762a and 766a, second barrier layers 762b and 766b, or active layer 764) may be selected to reduce the internal electric filed.

As mentioned above, Equations [6]-[7] may be used to calculate the strain in each layer of light emitting layer 760. Equations [6]-[7] may provide as a solution the strain in each position of each layer when a dimension (i.e., an area and a thickness) and/or composition of each layer are given. In some embodiments, a strain for each position of each layer (i.e., first barrier layers 762a and 766a, second barrier layers 762b and 766b, and active layer 764) may be calculated from Equations [6]-[7] based on thickness, area, and composition of each layer (i.e., first barrier layers 762a and 766a, second barrier layers 762b and 766b, and active layer 764). Further, in some embodiments, a strain for each position of each barrier sub-layer 762b₁ to 762bₙ and 766b₁ to 766bₙ may be calculated from Equations [6]-[7] based on thickness, area, and composition of each layer (i.e., first barrier layers 762a and 766a, each barrier sub-layer 762b₁ to 762bₙ and 766b₁ to 766bₙ of second barrier layers 762b and 766b, and active layer 764). With specific values for the thickness and area of each layer, a strain for each position of a layer may be computed from Equations [6]-[7], and a strain in a layer may be obtained by averaging the strains at the positions in the layer.

In some embodiments, Equations [8]-[12] may be used to calculate the internal electric field in active layer 764. The above strains calculated from Equations [6]-[7] may be used to solve Equations [8]-[12] so that the internal electric field in active layer 764 can be computed. In some embodiments, various internal electric fields according to the strains may be computed from Equations [8]-[12], and can be used to determine the strain which generates a minimum internal electric field.

Table 5 shows the calculation results of Equations [6]-[7] and Equations [8]-[12] for various thicknesses of first barrier layers 762a and 766a. The calculations are based on the assumption that active layer 764 has a thickness of about 3 nm and a composition of In_{0.2}Ga_{0.8}N, and first barrier layer 762a has a composition of GaN. Further, it is assumed that second barrier layer 762b includes barrier sub-layers 762b₁ to 762b₁₀ wherein each barrier sub-layer 762b₁ to 762b₁₀ has a thickness of about 0.3 nm, and wherein barrier sub-layers 762b₁, 762b₃, 762b₅, 762b₇, 762b₉ have a composition of In_{0.2}Ga_{0.8}N and barrier sub-layers 762b₂, 762b₄, 762b₆, 762b₈, 762b₁₀ have a composition of GaN. Further, it is assumed that first and second cladding layers 762 and 766 are symmetrical with respect to active layer 764. Therefore, it is assumed first barrier layer 762a has the same thickness and composition as first barrier layer 766a, and second barrier layer 766b has barrier sub-layers 766b₁ to 766b₁₀ which have the same compositions and thicknesses as barrier sub-layers 762a₁₀ to 762a₁, respectively.

In the Table 5, first and second cladding layer have the same strain due to the assumption that first and second cladding layers 762 and 766 are symmetrical with respect to active layer 764.

TABLE 5

| | first barrier layer's | | |
|---|---|---|---|
| | thickness | | |
| | 2 nm | 4 nm | 6 nm |
| Strain in active layer (%) | −2.005 | −1.92 | −1.87 |
| Strain in cladding layer | −0.105 | −0.059 | −0.021 |
| (%) | | | |
| Internal electric field | 2.581 | 2.509 | 2.484 |
| in active layer (MV/cm) | | | |

Referring to Table 5, when the strain in active layer 764 is −1.87% and strains in first and second cladding layers 762 and 766 are −0.021%, active layer 764 has a small internal electric field of 2.484 MV/cm. Therefore, a thickness of 6 nm can be selected for first barrier layers 762a and 766a to reduce the internal electric field. Further, the data in Table 5 shows that the internal electric field increases as the thickness of first barrier layers 762a and 766a increases. Therefore, the thickness of first barrier layers 762a and 766a may be increased within the size limit of the application.

Table 6 shows the calculation results of Equations [6]-[7] and Equations [8]-[12] for various compositions of second barrier layers 762b to 766b. Specifically, Equations [6]-[7] and Equations [8]-[12] are calculated for various light emitting layers 760 where compositions of barrier sub-layers 762b₁, 762b₃, 762b₅, 762b₇, 762b₉ are varied while barrier sub-layers 762b₂, 762b₄, 762b₆, 762b₈, 762b₁₀ have a composition of GaN. The calculations are based on the assumption that active layer 764 has a thickness of 3 nm and a composition of In_{0.2}Ga_{0.8}N, and first barrier layer 762a has a thickness of 6 nm and a composition of GaN. Further, it is assumed that second barrier layer 562b has a thickness of 6 nm and a composition of GaN, and each barrier sub-layer 762b₁ to 762b₁₀ has a thickness of 0.6 nm. Further, it is assumed that first and second cladding layers 762 and 766 are symmetrical with respect to active layer 764. Therefore, it is assumed second barrier layer 766b has the same thickness and composition as second barrier layer 762b. Further, it is assumed that second barrier layer 766b has barrier sub-layers 766b₁ to 766b₁₀ which have the same compositions and thicknesses as barrier sub-layers 762b₁₀ to 762b₁, respectively.

In the Table 6, first and second cladding layers 762 and 766 have the same strain due to the assumption that first and second cladding layers 762 and 766 are symmetrical with respect to active layer 764.

TABLE 6

| | first barrier layer's | |
|---|---|---|
| | compositions | |
| | In_{0.2}Ga_{0.8}N/GaN | In_{0.1}Ga_{0.9}N/GaN |
| Strain in active layer (%) | −1.081 | −1.098 |
| Strain in cladding layer (%) | −0.087 | −0.91 |
| Internal electric field | 1.71 | 1.89 |
| in active layer (MV/cm) | | |

As indicated in Table 6, when a strain in active layer 764 is −1.081% and strains in first and second cladding layers 762 and 766 are −0.087%, active layer 764 has a smaller internal electric field of 1.71 MV/cm. Therefore, a composition of In_{0.2}Ga_{0.8}N/GaN may be selected for second barrier layers 762b and 766b to reduce the internal electric field.

The data in Tables 5 and 6 is for a light emitting layer, such as light emitting layer 760, which is not in contact with the other layers so that the strains and the internal electric field may be changed when the light emitting layer is in contact with one or more of the other layers, such as substrate 120 or buffer layer 140 in FIG. 1, and the electrode pad is provided over the light emitting layer.

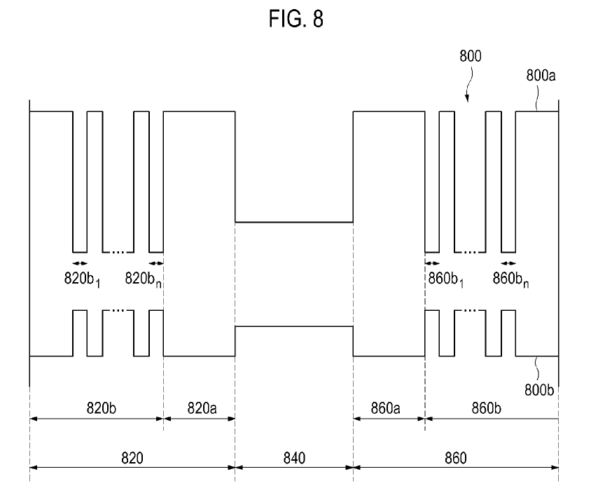

FIG. 8 is an energy band diagram 800 schematically illustrating a conduction band 800a and a valence band 800b of light emitting layer 760 having a multiple quantum well structure shown in FIG. 7. Reference numerals 820, 840 and 860 in FIG. 8 represent the regions of first cladding layer 762, active layer 764, and second cladding layer 766, respectively Reference numerals 820a and 820b represent the regions of first barrier layer 762a and second barrier layer 762b of first cladding layer 762, respectively. Reference numerals 860a and 860b represent the regions of first barrier layer 766a and second barrier layer 766b of the second cladding layer 766, respectively. Reference numerals 820b₁ to 820bₙ represent the regions of barrier sub-layers 762b₁ to 762bₙ of first cladding layer 762, respectively, and reference numerals 860b₁ to 860bₙ represent the regions of barrier sub-layers 766b₁ to 766bₙ of second cladding layer 766, respectively.

Referring to FIG. 8, first barrier layer 762a of first cladding layer 762 and first barrier layer 766a of second cladding layer 766 may have an energy band gap which is wider than that of active layer 764. Some barrier sub-layers 762b₁ to 762bₙ may have a wider band gap than other barrier sub-layers 762b₁ to 762bₙ. In some embodiments, second barrier layer 762b of first cladding layer 762 may have a multiple quantum well structure where at least one barrier sub-layer 762bᵢ is sandwiched between barrier sub-layers 762bᵢ₋₁ and 762bᵢ₊₁ which have a wider energy band gap than barrier sub-layer 762bᵢ. In some embodiments, the width of each quantum well may be different from each other.

Second barrier layer 766b of second cladding layer 766 may have a multiple quantum well structure where at least one barrier sub-layer 766bᵢ is sandwiched between barrier sub-layers 766bᵢ₋₁ and 766bᵢ₊₁ which have a wider energy band gap than barrier sub-layer 766bᵢ. Although light emitting layer 760 is illustrated as a multiple quantum well structure being provided in both second barrier layer 762b and second barrier layer 766b, it should be appreciated that at least second barrier layer 762b or second barrier layer 766b may have a multiple quantum well structure. FIG. 8 shows that light emitting layer 760 with the multiple barrier structure has a symmetrical energy band gap diagram, although in other embodiments the energy band gap is not symmetrical. It should be appreciated that the energy band diagram may be modified in various ways.

The present disclosure is not to be limited in terms of the particular embodiments described in this application, which are intended as illustrations of various aspects. Many modifications and variations can be made without departing from its spirit and scope. Functionally equivalent methods and apparatuses within the scope of the disclosure, in addition to those enumerated herein, will be apparent. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, it should be appreciated that these terms translate from the plural to the singular and/or from the singular to the plural as is appropriate to the context and/or application. The various singular/plural permutations may be expressly set forth herein for sake of clarity.

It should be further appreciated that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It should be further understood that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, it should be recognized that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one would understand the convention (e.g., “a system having at least one of A, B, or C” would include but not be limited to systems that have A alone, B alone, C alone, A and B together, A and C together, B and C together, and/or A, B, and C together, etc. ). It should be further understood that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, it is recognized that the disclosure is also thereby described in terms of any individual member or subgroup of members of the Markush group.

It should be further understood, for any and all purposes, such as in terms of providing a written description, all ranges disclosed herein also encompass any and all possible subranges and combinations of subranges thereof Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. It should also be understood that all language such as “up to,” “at least,” and the like include the number recited and refer to ranges which can be subsequently broken down into subranges as discussed above. Finally, it should also be understood that a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A structure comprising:
a first cladding layer comprising at least two barrier layers which have different energy band gaps, the first cladding layer doped with a first dopant;
an active layer located on the first cladding layer and comprising an active layer energy band gap which has a smaller energy band gap than at least one of the energy band gaps of the at least two barrier layers of the first cladding layer; and
a second cladding layer located on the active layer and comprising at least two barrier layers which have different energy band gaps, the second cladding layer doped with a second dopant different than the first dopant, and at least one of the two barrier layers of the second cladding layer having a larger energy band gap than the active layer band gap.

2. The structure of claim 1, wherein the first cladding layer comprises:
a first barrier layer having a first energy band gap; and
a second barrier layer located on the first barrier layer and having a second energy band gap,
wherein the second energy band gap is wider than the first energy band gap.

3. The structure of claim 1, wherein the second cladding layer comprises:
a third barrier layer having a third energy band gap; and
a fourth barrier layer located on the third barrier layer and having a fourth energy band gap,
wherein the fourth energy band gap is wider than the third energy band gap.

4. The structure of claim 2, wherein the second barrier layer comprises second barrier sub-layers having second barrier sub-layer energy band gaps, wherein an energy band gap difference between the second barrier sub-layer energy band gaps and the active layer energy band gap is inversely proportional to a distance between the corresponding second barrier sub-layer and the active layer.

5. The structure of claim 3, wherein the third barrier layer comprises third barrier sub-layers having third barrier sub-layer energy band gaps, wherein an energy band gap difference between the third barrier sub-layer energy band gaps and the active layer energy band gap is proportional to a distance between the corresponding third barrier sub-layer and the active layer.

6. The structure of claim 4, wherein the second cladding layer comprises:
a third barrier layer having a third energy band gap; and
a fourth barrier layer located on the third barrier layer and having a fourth energy band gap,
wherein the fourth energy band gap is wider than the third energy band gap, and
wherein the third barrier layer includes third barrier sub-layers having third barrier sub-layer energy band gaps, wherein a energy band gap difference between the third barrier sub-layer energy band gaps and the active layer energy band gap is proportional to a distance between the corresponding third barrier sub-layer and the active layer.

7. The structure of claim 1, further comprising a substrate under the first cladding layer.

8. The structure of claim 7, further comprising a buffer layer between the substrate and the first cladding layer.

9. The structure of claim 1, wherein the first cladding layer and the second cladding layer comprise at least one of CdZnO or MgZnO, and the active layer comprises ZnO.

10. The structure of claim 1, wherein the first cladding layer and the active layer comprise InGaN, and the second cladding layer comprises GaN.

11. The structure of claim 10, wherein an indium concentration of the first cladding layer is smaller than an indium concentration of the active layer.

12. A structure comprising:
a first cladding layer doped with a first dopant; the first cladding layer comprising:
a first barrier layer comprising first barrier sub-layers; and
a second barrier layer located on the first cladding layer;
an active layer located on the second barrier layer; and
a second cladding layer located on the active layer, the second cladding layer doped with a second dopant different than the first dopant,
wherein the first barrier sub-layers have first barrier sub-layer energy band gaps to form multiple quantum wells.

13. The structure of claim 12, wherein the second cladding layer comprises a third barrier layer located on the active layer and a fourth barrier layer located on the third barrier layer, and
wherein the fourth barrier layer includes fourth barrier sub-layers having second barrier sub-layer energy band gaps to form multiple quantum wells.

14. A method for fabricating an optoelectronic device, the method comprising:
forming a first cladding layer having a least two barrier layers which have different energy band gaps, the first cladding layer doped with a first dopant;
forming an active layer on the first cladding layer, the active layer having an active layer energy band gap which has a smaller energy band gap than at least one of the energy band gaps of the at least two barrier layers of the first cladding layer; and
forming a second cladding layer on the active layer, the second cladding layer having at least two barrier layers which have different energy band gaps, the second cladding layer doped with a second dopant different than the first dopant and at least one of the two barrier layers of the second cladding layer having a larger energy band gap than the active layer band gap.

15. The method of claim 14, wherein forming a first cladding layer comprises: forming a first barrier layer having a first energy band gap; and
forming a second barrier layer having a second energy band gap on the first barrier layer,
wherein the second energy band gap is wider than the first energy band gap.

16. The method of claim 14, wherein forming a second cladding layer comprises:
forming a third barrier layer having a third energy band gap; and
forming a fourth barrier layer on the third barrier layer,
wherein the fourth energy band gap is wider than the third energy band gap.

17. The method of claim 15, wherein forming a second barrier layer comprises:
forming second barrier sub-layers having a second barrier sub-layer energy band gaps,
wherein a energy band gap difference between the second barrier sub-layer energy band gaps and the active layer energy band gap is inversely proportional to a distance between the corresponding second barrier sub-layer and the active layer.

18. The method of claim 16, wherein forming a third barrier layer comprises:
forming third barrier sub-layers having third barrier sub-layer energy band gaps,
wherein a energy band gap difference between the third barrier sub-layer energy band gaps and the active layer energy band gap is proportional to a distance between the corresponding third barrier sub-layer and the active layer.

19. A method for fabricating an optoelectronic device, the method comprising:
forming a first cladding layer doped with a first dopant, the first cladding layer comprising a first barrier layer and a second barrier layer located on the first cladding layer,
forming an active layer located on the first cladding layer; and
forming a second cladding layer located on the active layer, the second cladding layer doped with a second dopant different than the first dopant,
wherein the first barrier layer comprises first barrier sub-layers having first barrier sub-layer energy band gaps to form multiple quantum wells.

20. The method of claim 19, wherein forming a second cladding layer comprises:
forming a third barrier layer on the active layer; and
forming a fourth barrier layer on the third barrier layer,
wherein the fourth barrier layer comprises fourth barrier sub-layers having second barrier sub-layer energy band gaps to form multiple quantum wells.
